(19) United States
(12) Patent Application Publication
(10) Pub. No.: US 2026/0150418 A1
(43) Pub. Date: May 28, 2026

(54) PHOTODETECTOR, ELECTRONIC APPARATUS, AND OPTICAL ELEMENT

(71) Applicant: SONY SEMICONDUCTOR SOLUTIONS CORPORATION, Kanagawa (JP)

(72) Inventors: Haruka KATONO, Kanagawa (JP); Yoshinori TOUMIYA, Kanagawa (JP); Hiroshi SAITO, Kanagawa (JP); Yusuke MORIYA, Kanagawa (JP)

(73) Assignee: SONY SEMICONDUCTOR SOLUTIONS CORPORATION, Kanagawa (JP)

(21) Appl. No.: 19/120,310

(22) PCT Filed: Oct. 5, 2023
(86) PCT No.: PCT/JP2023/036440

§ 371 Date: Apr. 11, 2025

(30) Foreign Application Priority Data
Oct. 20, 2022 (JP) 2022-168356

(51) Int. Cl. H10F 39/00; G02B 1/118; H04N 23/55

(52) U.S. Cl. CPC H10F 39/806; G02B 1/118; H10F 39/805; H04N 23/55

(57) ABSTRACT

There is provided a photodetector. The photodetector includes a light guide including a plurality of structures each having a size equal to or less than a wavelength of incident light, a first material, a second material, wherein a combination of the first material and the second material is provided above and/or between the plurality of structures and wherein the first material and the second material each has a refractive index different from a refractive index of the plurality of structures and a photoelectric converter that photoelectrically converts light incident via the light guide.

### CROSS REFERENCE TO RELATED APPLICATIONS

This application claims the benefit of Japanese Priority Patent Application JP 2022-168356 filed Oct. 20, 2022, the entire contents of which are incorporated herein by reference.

### TECHNICAL FIELD

The present disclosure relates to a photodetector, an electronic apparatus, and an optical element.

### BACKGROUND ART

An image sensor provided with a color separating lens array including a plurality of nanoposts has been proposed (PTL 1).

### CITATION LIST

### Patent Literature [PTL 1] Japanese Unexamined Patent Application Publication No. 2021-69119

### SUMMARY

### Technical Problem

A device to detect light is required to prevent deterioration in quality.

It is desirable to provide a photodetector that makes it possible to prevent deterioration in quality.

### Solution to Problem

A photodetector according to an embodiment of the present disclosure includes a lightguide including a plurality of structures each having a size equal to or less than a wavelength of incident light, a first material, a second material, wherein a combination of the first material and the second material is provided above and/or between the plurality of structures and wherein the first material and the second material each has a refractive index different from a refractive index of the plurality of structures and a photoelectric converter that photoelectrically converts light incident via the lightguide. An optical element according to an embodiment of the present disclosure includes a plurality of structures each having a size equal to or less than a wavelength of incident light, a first material and a second material, wherein combination of the first material and the second material is provided above and/or between the plurality of structures and wherein the first material and the second material each has a refractive index different from a refractive index of the plurality of structures.

An electronic apparatus according to an embodiment of the present disclosure includes an optical system and a photodetector that receives light transmitted through the optical system. The photodetector includes a light guide including a plurality of structures each having a size equal to or less than a wavelength of incident light, a first material, a second material, wherein a combination of the first material and the second material is provided above and/or between the plurality of structures and wherein the first material and second material each has a refractive index different from a refractive index of the plurality of structures and a photoelectric converter that photoelectrically converts light incident via the light guide.

### BRIEF DESCRIPTION OF DRAWINGS

FIG. 1 is a block diagram illustrating an example of a schematic configuration of an imaging device which is an example of a photodetector according to an embodiment of the present disclosure.

FIG. 2 is a diagram illustrating an example of a pixel section of the imaging device according to the embodiment of the present disclosure.

FIG. 3 is a diagram illustrating a configuration example of a pixel of the imaging device according to the embodiment of the present disclosure.

FIG. 4 is a diagram illustrating an example of a cross-sectional configuration of the imaging device according to the embodiment of the present disclosure.

FIG. 5A is a diagram illustrating an example of a planar configuration of a light-guiding section of the imaging device according to the embodiment of the present disclosure.

FIG. 5B is a diagram illustrating an example of a planar configuration of the light-guiding section of the imaging device according to the embodiment of the present disclosure.

FIG. 6A is a diagram illustrating a configuration example of an imaging device according to a comparative example.

FIG. 6B is a diagram illustrating a configuration example of the imaging device according to the comparative example.

FIG. 7A is a diagram illustrating a configuration example of the imaging device according to the embodiment of the present disclosure.

FIG. 7B is a diagram illustrating a configuration example of the imaging device according to the embodiment of the present disclosure.

FIG. 8 is a diagram illustrating a configuration example of an imaging device according to a comparative example.

FIG. 9 is a diagram illustrating a configuration example of the imaging device according to the embodiment of the present disclosure.

FIG. 10 is an explanatory diagram of a configuration example of the light-guiding section of the imaging device according to the embodiment of the present disclosure.

FIG. 11A is a diagram illustrating an example of a method of manufacturing the imaging device according to the embodiment of the present disclosure.

FIG. 11B is a diagram illustrating an example of the method of manufacturing the imaging device according to the embodiment of the present disclosure.

FIG. 11C is a diagram illustrating an example of the method of manufacturing the imaging device according to the embodiment of the present disclosure.

FIG. 11D is a diagram illustrating an example of the method of manufacturing the imaging device according to the embodiment of the present disclosure.

FIG. 11E is a diagram illustrating an example of the method of manufacturing the imaging device according to the embodiment of the present disclosure.

FIG. 11F is a diagram illustrating an example of the method of manufacturing the imaging device according to the embodiment of the present disclosure.

FIG. 12A is a diagram illustrating another example of the method of manufacturing the imaging device according to the embodiment of the present disclosure.

FIG. 12B is a diagram illustrating another example of the method of manufacturing the imaging device according to the embodiment of the present disclosure.

FIG. 12C is a diagram illustrating another example of the method of manufacturing the imaging device according to the embodiment of the present disclosure.

FIG. 12D is a diagram illustrating another example of the method of manufacturing the imaging device according to the embodiment of the present disclosure.

FIG. 12E is a diagram illustrating another example of the method of manufacturing the imaging device according to the embodiment of the present disclosure.

FIG. 12F is a diagram illustrating another example of the method of manufacturing the imaging device according to the embodiment of the present disclosure.

FIG. 12G is a diagram illustrating another example of the method of manufacturing the imaging device according to the embodiment of the present disclosure.

FIG. 12H is a diagram illustrating another example of the method of manufacturing the imaging device according to the embodiment of the present disclosure.

FIG. 12I is a diagram illustrating another example of the method of manufacturing the imaging device according to the embodiment of the present disclosure.

FIG. 12J is a diagram illustrating another example of the method of manufacturing the imaging device according to the embodiment of the present disclosure.

FIG. 13 is a diagram illustrating a configuration example of a light-guiding section of an imaging device according to Modification Example 1 of the present disclosure.

FIG. 14 is a diagram illustrating a configuration example of a light-guiding section of an imaging device according to Modification Example 2 of the present disclosure.

FIG. 15 is a diagram illustrating a configuration example of an imaging device according to Modification Example 3 of the present disclosure.

FIG. 16 is a block diagram illustrating a configuration example of an electronic apparatus including the imaging device.

FIG. 17 is a block diagram depicting an example of a schematic configuration of a vehicle control system.

FIG. 18 is a diagram of assistance in explaining an example of installation positions of an outside-vehicle information detecting section and an imaging section.

FIG. 19 is a view depicting an example of a schematic configuration of an endoscopic surgery system.

FIG. 20 is a block diagram depicting an example of a functional configuration of a camera head and a camera control unit (CCU).

### DESCRIPTION OF EMBODIMENTS

Hereinafter, a description is given in detail of embodiments of the present disclosure with reference to the drawings. It is to be noted that the description is given in the following order.
1. Embodiment
2. Modification Examples
3. Application Example
4. Practical Application Examples

### 1. Embodiment

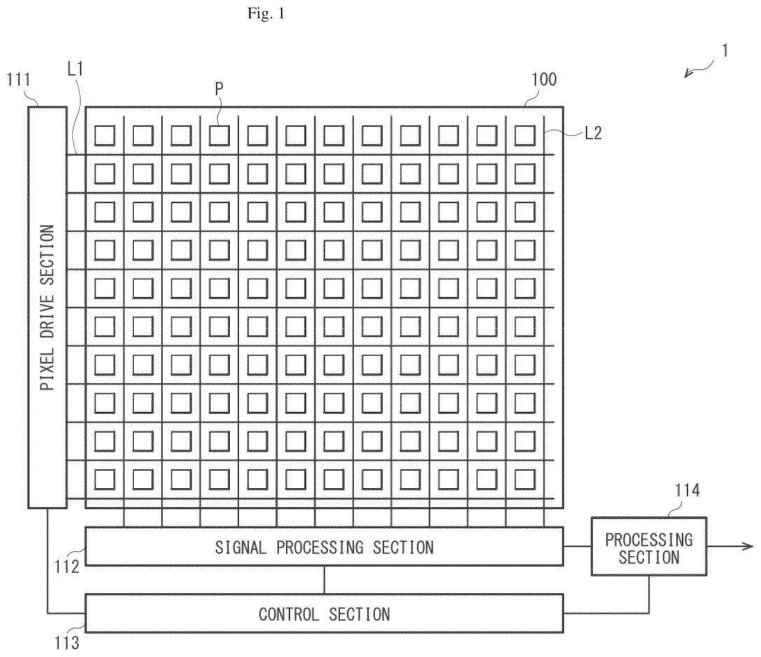

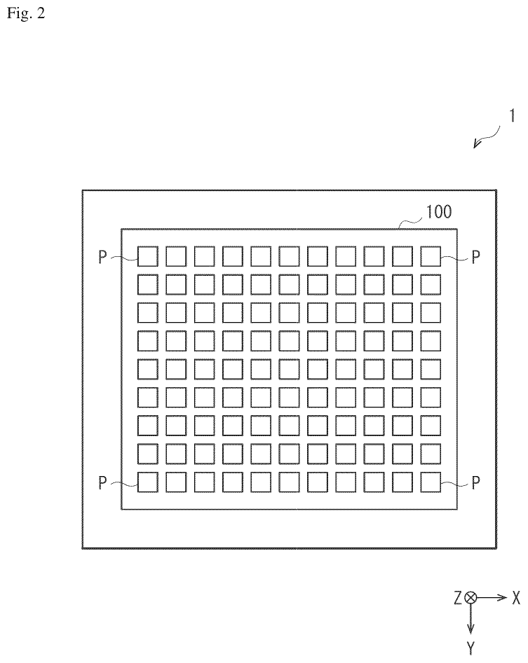

FIG. 1 is a block diagram illustrating an example of a schematic configuration of an imaging device which is an example of a photodetector according to an embodiment of the present disclosure. FIG. 2 is a diagram illustrating an example of a pixel section of the imaging device according to the embodiment. The photodetector is a device that is able to detect incoming light. An imaging device 1, which is the photodetector, can receive light transmitted through an optical system to generate a signal. The imaging device 1 (photodetector) includes a plurality of pixels P each including a photoelectric conversion section and is configured to photoelectrically convert incident light to generate a signal.

The photoelectric conversion section of each of the pixels P of the imaging device 1 is, for example, a photodiode, and is configured to be able to photoelectrically convert light. As illustrated in FIG. 2, the imaging device 1 includes, as an imaging area, a region (a pixel section 100) in which the plurality of pixels P are two-dimensionally arranged in matrix. The pixel section 100 is a pixel array in which the plurality of pixels P are arranged and can also be referred to as a light-receiving region.

The imaging device 1 takes in incident light (image light) from a subject via an optical system (unillustrated) including an optical lens. The imaging device 1 captures an image of the subject formed by the optical lens. The imaging device 1 can photo-electrically convert received light to generate a pixel signal. The imaging device 1 is, for example, a CMOS (Complementary Metal Oxide Semiconductor) image sensor.

The imaging device 1 is usable for an electronic apparatus such as a digital still camera, a video camera, or a mobile phone.

It is to be noted that, as illustrated in FIG. 2, a direction in which light from the subject is incident is defined as a Z-axis direction; a right-left direction on the plane orthogonal to the Z-axis direction is defined as an X-axis direction; and an up-down direction on the plane orthogonal to the Z-axis and the X-axis is defined as a Y-axis direction. In the following drawings, the arrow directions in FIG. 2 may be used, in some cases, as a standard to express a direction.

As in the example illustrated in FIG. 1, the imaging device 1 includes, in a peripheral region of the pixel section 100 (pixel array), for example, a pixel drive section 111, a signal processing section 112, a control section 113, a processing section 114, and the like. In addition, the imaging device 1 is provided with a plurality of control lines L1 and a plurality of signal lines L2.

The imaging device 1 is provided with the control line L1 which is a signal line that can transmit a signal to control the pixel P. In the pixel section 100, for example, the plurality of control lines L1 are wired for respective pixel rows each configured by the plurality of pixels P arranged in a horizontal direction (row direction). The control line L1 is configured to transmit a control signal to read a signal from the pixel P. The control line L1 may be referred to as a pixel drive line that transmits a signal to drive the pixel P.

In addition, the imaging device 1 is provided with a signal line L2 which is a signal line that is able to transmit a signal from the pixel P. In the pixel section 100, for example, signal lines L2 are wired for respective pixel columns each configured by a plurality of pixels P arranged in a vertical direction (column direction). The signal line L2 is a vertical signal line and is configured to transmit an output signal from the pixel P.

The pixel drive section 111 is configured by a shift register, an address decoder, and the like. The pixel drive section 111 is configured to be able to drive each of the pixels P of the pixel section 100. The pixel drive section 111 generates a signal to control the pixel P, and outputs the signal to each of the pixels P of the pixel section 100 via the control line L1.

As described later, for example, the pixel drive section 111 generates a signal to control a transfer transistor of the pixel P, a signal to control a reset transistor, or the like, and supplies the signal to each of the pixels P by the control line L1. The pixel drive section 111 can perform control to read a pixel signal from each of the pixels P. The pixel drive section 111 may also be referred to as a pixel control section configured to be able to control each of the pixels P.

The signal processing section 112 is configured to be able to execute signal processing of an inputted pixel signal. The signal processing section 112 includes, for example, a load circuit part, an AD (Analog-to-Digital) converter part, a horizontal selection switch, and the like. The signal output from each of the pixels P selected and scanned by the pixel drive section 111 is inputted to the signal processing section 112 via the signal line L2. The signal processing section 112 can perform signal processing such as CDS (Correlated Double Sampling: correlated double sampling) and AD conversion of the signal of the pixel P. The signal of each of the pixels P transmitted through each of the signal lines L2 is subjected to signal processing by the signal processing section 112, and output to the processing section 114.

The processing section 114 is configured to be able to execute signal processing on an inputted signal. The processing section 114 is configured by, for example, a circuit that performs various types of signal processing on a pixel signal. The processing section 114 may include a processor and a memory. The processing section 114 performs signal processing on the pixel signal input from the signal processing section 112, and outputs the processed pixel signal. The processing section 114 can perform, for example, various types of signal processing such as noise reduction processing or gradation correction processing.

The control section 113 is configured to be able to control each section of the imaging device 1. The control section 113 can receive a clock supplied from the outside, data ordering an operation mode, or the like, and output data such as internal information on the imaging device 1. The control section 113 includes a timing generator configured to be able to generate various timing signals. The control section 113 controls driving of a peripheral circuit such as the pixel drive section 111 and the signal processing section 112 based on the various timing signals (pulse signals, clock signals, and the like) generated by the timing generator. It is to be noted that the control section 113 and the processing section 114 may be integrally configured.

The pixel drive section 111, the signal processing section 112, the control section 113, the processing section 114, and the like may be provided in one semiconductor substrate or may be provided separately in a plurality of semiconductor substrates. The imaging device 1 may have a structure (stacked structure) configured by stacking a plurality of substrates.

### Configuration of Pixel

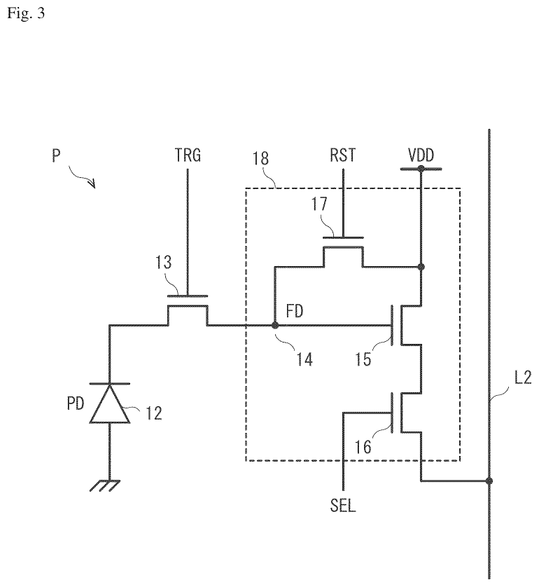

FIG. 3 is a diagram illustrating a configuration example of a pixel of an imaging device according to the embodiment. The pixel P includes a photoelectric conversion section 12, a transfer transistor 13, an FD (floating diffusion) 14, and a readout circuit 18. The readout circuit 18 is configured to be able to output a signal based on electric charge having undergone photoelectric conversion. As an example, the readout circuit 18 includes an amplification transistor 15, a selection transistor 16, and a reset transistor 17. It is to be noted that the readout circuit 18 may include the FD 14.

The transfer transistor 13, the amplification transistor 15, the selection transistor 16, and the reset transistor 17 are each an MOS transistor (MOSFET) including terminals of a gate, a source, and a drain. In the example illustrated in FIG. 3, the transfer transistor 13, the amplification transistor 15, the selection transistor 16, and the reset transistor 17 are each configured by an NMOS transistor. It is to be noted that the transistor of the pixel P may be configured by a PMOS transistor.

The photoelectric conversion section 12 is configured to be able to generate electric charge by photoelectric conversion. The photoelectric conversion section 12 is, for example, a photodiode (PD) embedded and formed in a semiconductor substrate and converts incoming light into electric charge. The photoelectric conversion section 12 performs photoelectric conversion to generate electric charge corresponding to a received light amount.

The transfer transistor 13 is configured to be able to transfer the electric charge photoelectrically converted by the photoelectric conversion section 12 to the FD 14. As illustrated in FIG. 3, the transfer transistor 13 is controlled by a signal TRG to electrically couple or decouple the photoelectric conversion section 12 and the FD 14 to or from each other. The transfer transistor 13 can transfer electric charge photoelectrically converted and accumulated by the photoelectric conversion section 12 to the FD 14.

The FD 14 is an accumulation section and is configured to be able to accumulate the transferred electric charge. The FD 14 can accumulate electric charge photoelectrically converted by the photoelectric conversion section 12. The FD 14 can also be referred to as a holding section that is able to hold the transferred electric charge. The FD 14 accumulates and converts the transferred electric charge into a voltage corresponding to a capacity of the FD 14.

The amplification transistor 15 is configured to generate and output a signal based on the electric charge accumulated in the FD 14. As illustrated in FIG. 3, a gate of the amplification transistor 15 is electrically coupled to the FD 14 to allow the voltage converted by the FD 14 to be input thereto. A drain of the amplification transistor 15 is coupled to a power supply line to be supplied with a power supply voltage VDD, and a source of the amplification transistor 15 is coupled to the signal line L2 via the selection transistor 16. The amplification transistor 15 can generate a signal based on the electric charge accumulated in the FD 14, i.e., a signal based on the voltage of the FD 14 and output the generated signal to the signal line L2.

The selection transistor 16 is configured to be able to control the output of a pixel signal. The selection transistor 16 is controlled by a signal SEL and is configured to be able to output the signal from the amplification transistor 15 to the signal line L2. The selection transistor 16 can control the output timing of the pixel signal. It is to be noted that the selection transistor 16 may be provided between the power supply line to be supplied with the power supply voltage VDD and the amplification transistor 15. In addition, the selection transistor 16 may be omitted, as needed.

The reset transistor 17 is configured to be able to reset the voltage of the FD 14. In the example illustrated in FIG. 3, the reset transistor 17 is electrically coupled to the power supply line to be supplied with the power supply voltage VDD, and is configured to reset electric charge of the pixel P. The reset transistor 17 can be controlled by a signal RST to reset the electric charge accumulated in the FD 14 and to reset the voltage of the FD 14. It is to be noted that the reset transistor 17 can discharge the electric charge accumulated in the photoelectric conversion section 12 via the transfer transistor 13.

The pixel drive section 111 (see FIG. 1) supplies a control signal to the gates of the transfer transistor 13, the selection transistor 16, the reset transistor 17, and the like of each of the pixels P via the above-described control line L1, to bring the transistors into an ON state (an electrically-conductive state) or an OFF state (a non-electrically-conductive state). The plurality of control lines L1 of the imaging device 1 includes a wiring line that transmits the signal TRG to control the transfer transistor 13, a wiring line that transmits the signal SEL to control the selection transistor 16, a wiring line that transmits the signal RST to control the reset transistor 17, and the like.

The transfer transistor 13, the selection transistor 16, the reset transistor 17, and the like are controlled to be turned ON or OFF by the pixel drive section 111. The pixel drive section 111 controls the readout circuit 18 of each of the pixels P to thereby cause each of the pixels P to output a pixel signal to the signal line L2. The pixel drive section 111 can perform control to read the pixel signal of each of the pixels P to the signal line L2. It is to be noted that the pixel drive section 111 and the control section 113 may also be collectively referred to as the pixel control section.

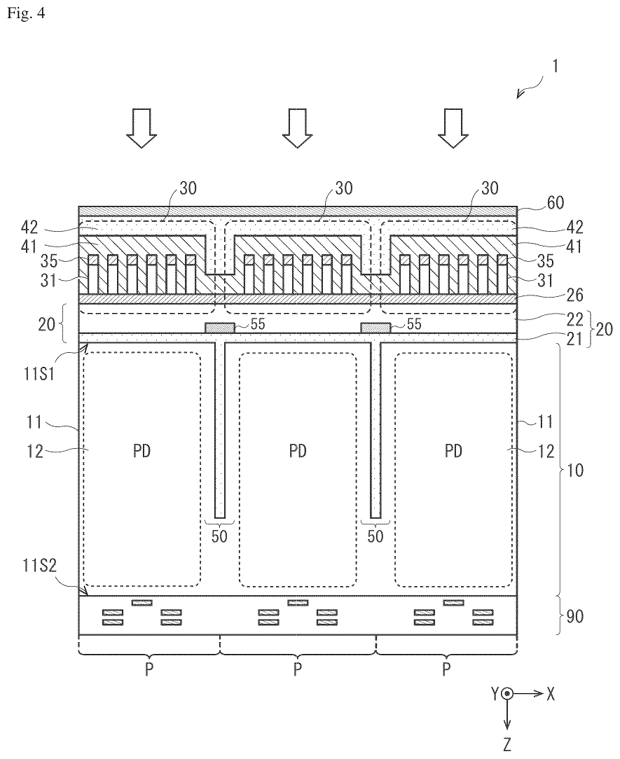

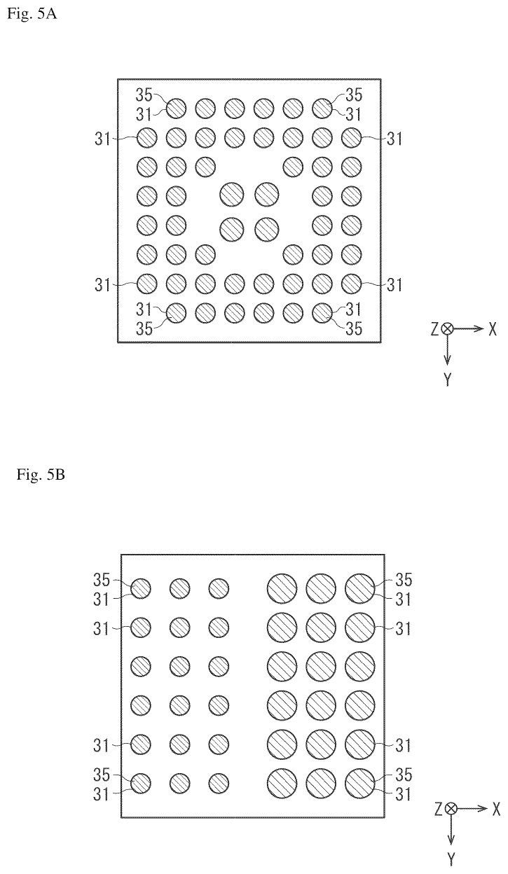

FIG. 4 is a diagram illustrating an example of a cross-sectional configuration of an imaging device according to the embodiment. FIGS. 5A and 5B are each a diagram illustrating an example of a planar configuration of a light-guiding section of the imaging device according to the embodiment. As illustrated in FIG. 4, the imaging device 1 has a configuration in which, for example, a light-guiding section 30, an insulating layer 20, a light-receiving section 10, and a multilayer wiring layer 90 are stacked in the Z-axis direction.

The light-receiving section 10 includes a semiconductor substrate 11 having a first surface 11S1 and a second surface 11S2 opposed to each other. The semiconductor substrate 11 is configured by, for example, a silicon substrate. The insulating layer 20, the light-guiding section 30, and the like are provided on a side of the first surface 11S1 of the semiconductor substrate 11. The multilayer wiring layer 90 is provided on a side of the second surface 11S2 of the semiconductor substrate 11. The light-guiding section 30 is provided on a side on which light from an optical system is incident, and the multilayer wiring layer 90 is provided on a side opposite the side on which light is incident. The imaging device 1 is a so-called back-illuminated imaging device.

In the light-receiving section 10, a plurality of photoelectric conversion sections 12 is provided between the first surface 11S1 and the second surface 11S2 of the semi-conductor substrate 11. For example, the plurality of photoelectric conversion sections 12 is embedded and formed in the semiconductor substrate 11. In addition, the semi-conductor substrate 11 is provided with a separation section 50.

The separation section 50 is provided between the photoelectric conversion sections 12 adjacent to each other to separate the photoelectric conversion sections 12 from each other. The separation section 50 is provided to surround the photoelectric conversion section 12 in the semiconductor substrate 11. The separation section 50 has a trench (a groove part) provided at a boundary between the pixels P (or the photoelectric conversion sections 12) adjacent to each other.

As an example, an insulating film, e.g., a silicone oxide film is provided inside the trench of the separation section 50. It is to be noted that polysilicon, a metal material, or the like may be embedded in the trench of the separation section 50. In addition, an air gap (cavity) may be provided inside the trench of the separation section 50. Providing the separation section 50 suppresses leakage of light to surrounding pixels P.

The multilayer wiring layer 90 has a configuration in which, for example, a plurality of wiring lines is stacked with an interlayer insulating layer (interlayer insulating film) interposed therebetween. The wiring layer of the multilayer wiring layer 90 is formed using, for example, aluminum (Al), copper (Cu), or the like. The wiring layer may be formed using polysilicon (Poly-Si). As an example, the interlayer insulating layer is formed using, for example, silicon oxide (SiOx), silicon nitride (SiNx), silicon oxynitride (SiOxNy), or the like.

The semiconductor substrate 11 and the multilayer wiring layer 90 are provided with, for example, the readout circuit 18 described above. It is to be noted that the pixel drive section 111, the signal processing section 112, the control section 113, and the processing section 114 described above may be formed in a substrate different from the semiconductor substrate 11 or in the semiconductor substrate 11 and the multilayer wiring layer 90.

The insulating layer 20 is provided between a layer provided with the light-guiding section 30 and the light-receiving section 10. The insulating layer 20 includes an insulating film 21 and an insulating film 22. The insulating film 21 is provided on the first surface 11S1 of the semiconductor substrate 11. The insulating film 22 is stacked on the insulating film 21 and is positioned on the insulating film 21.

The insulating layer 20 is formed using, for example, an oxide film, a nitride film, an oxynitride film, or the like. The insulating film 21 and the insulating film 22 of the insulating layer 20 may each be configured by silicon oxide (SiO), TEOS, silicon nitride (SiN), silicon oxynitride (SiON), or the like, or may be configured using another insulating material. The insulating layer 20 can also be referred to as a planarization layer (planarization film). In the example illustrated in FIG. 4, a light-blocking section 55 is provided inside the insulating film 22 of the insulating layer 20.

The light-blocking section 55 (light-blocking film) is configured by a member that blocks light and is provided at a boundary between the plurality of pixels P adjacent to each other. The light-blocking section 55 is formed, for example, on the insulating film 21, and is positioned above the separation section 50 in the example illustrated in FIG. 4. The light-blocking section 55 is configured by, for example, a metal material (aluminum (Al), tungsten (W), copper (Cu), etc.) that blocks light. The light-blocking section 55 is provided around the photoelectric conversion section 12 to suppress leakage of light to surrounding pixels. It is to be noted that the light-blocking section 55 may be configured by a material that absorbs light.

It is to be noted that the imaging device 1 may include a fixed charge film between the photoelectric conversion section 12 and the insulating layer 20. The fixed charge film is configured by, for example, an oxide film (metal oxide film, etc.). In addition, the fixed charge film may be formed on the photoelectric conversion section 12 and between the photoelectric conversion section 12 and the separation section 50. The fixed charge film is, for example, a film having negative fixed electric charge, and suppresses generation of a dark current at an interface of the semiconductor substrate 11.

In addition, as illustrated in FIG. 4, the imaging device 1 includes an antireflection film 26 and a protective film 60. The antireflection film 26 is configured using, for example, an insulating material such as silicon nitride (SiN) or silicon oxide (SiO). In the example illustrated in FIG. 4, the antireflection film 26 is provided on the insulating film 22 to reduce (suppress) reflection. It is to be noted that the light-guiding section 30 or the insulating layer 20 may include the antireflection film 26.

The protective film 60 is provided on the light-guiding section 30, as illustrated in FIG. 4. The protective film 60 is a passivation film (protective layer) and is formed to cover the entirety of a plurality of light-guiding sections 30. The protective film 60 is configured by, for example, an inorganic material. As an example, the protective film 60 is configured by a silicon oxide film, a silicon nitride film, or the like.

The light-guiding section 30 includes a plurality of structures 31 and is configured to guide incident light to the light-receiving section 10. Light from a subject to be measured is incident on the light-guiding section 30. Each structure of the plurality of structures 31 is a fine (minute) structure having a size equal to or less than a predetermined wavelength of incoming light. Each structure 31 has, for example, a size equal to or less than a wavelength of visible light. Each structure 31 may have a size equal to or less than a wavelength of infrared light.

The light-guiding section 30 includes a plurality of materials (a first member 41 and a second member 42 in FIG. 4). A combination of the first member 41 and the second member 42 is provided above the plurality of structures 31 and/or is provided around the plurality of structures 31. A combination of the first member 41 and the second member 42 is provided between the plurality of structures 31. A combination of the first member 41 and the second member 42 is embedded between the plurality of structures 31. The first member 41 and the second member 42 are each a filling member and are provided between the plurality of structures 31. The first member 41 and the second member 42 can also be referred to as a first filling member and a second filling member, respectively.

In addition, the light-guiding section 30 includes an antireflection film 35, as illustrated in FIG. 4. The antireflection film 35 is configured using, for example, an insulating material such as silicon nitride (SiN) or silicon oxide (SiO). The antireflection film 35 is provided on each of the plurality of structures 31 to reduce (suppress) reflection.

The first member 41 and the second member 42 may be configured using different materials. In the present embodiment, the first member 41 is configured by an inorganic material and is provided in contact with the plurality of structures 31. The second member 42 is configured by an organic material and is provided on the first member 41. The first member 41 is formed to cover the plurality of structures 31 and the antireflection film 35, and the second member 42 is formed to cover the first member 41. The second member 42 is stacked on the first member 41 and is in contact with the first member 41.

The light-guiding section 30 is an optical element (optical member) that guides (propagates) light. The light-guiding section 30 (light guide) utilizes the plurality of structures 31, which are fine structures, to propagate light to the photoelectric conversion section 12. The light-guiding section 30 is provided for each pixel P or for each plurality of pixels P.

Each of the plurality of structures 31 is, for example, a columnar (pillar-shaped) structure, as illustrated in FIG. 4. As schematically illustrated in FIG. 4, the plurality of structures 31 are arranged side by side to each other in the right-left direction (X-axis direction) on the plane, with at least one of the first member 41 or the second member 42 interposed therebetween. In each of the pixels P of the imaging device 1, the plurality of structures 31 can be arranged at an interval equal to or less than a predetermined wavelength of incident light, e.g., at an interval equal to or less than a wavelength of visible light (or infrared light).

Each of the structures 31 has a refractive index different from a refractive index of a surrounding material. Each of the structures 31 has a refractive index different from refractive indexes of the first member 41 and the second member 42 which are material surrounding the plurality of structures 31. Each of the structures 31 has a refractive index higher than a refractive index of a surrounding material, for example.

Each of the structures 31 has a refractive index higher than the refractive index of the first member 41, for example. In addition, each of the structures 31 has a refractive index higher than the refractive index of the second member 42. Each of the structures 31 can be configured by a material having a refractive index higher than the refractive index of the first member 41 and the refractive index of the second member 42.

The first member 41 has a refractive index higher than the refractive index of the second member 42. The difference between the refractive index of each of the structures 31 and the refractive index of the first member 41 is, for example, 0.3 or more. It is to be noted that a difference between the refractive index of each of the structures 31 and the refractive index of the second member 42 is also, for example, 0.3 or more.

As an example, each of the structures 31 is configured using titanium oxide. Each of the structures 31 may be configured by a simple substance, oxide, nitride, oxynitride, or composite of titanium, hafnium, zirconium, tantalum, aluminum, niobium, indium, and the like. In addition, each of the structures 31 may be formed using silicon oxide, silicon nitride, silicon nitride oxide, silicon carbide, silicon oxide carbide, or another silicon compound.

Each of the structures 31 may be formed using amorphous silicon (a-Si), polysilicon, germanium (Ge), or the like. In addition, each of the structures 31 may be configured from an organic matter such as siloxane. For example, each of the structures 31 may be configured using a siloxane-based resin, a styrene-based resin, an acrylic-based resin, or the like. Each of the structures 31 may be configured by a material containing fluorine in any of these resins. Each of the structures 31 may be formed using a material in which any of these resins is filled with beads (filler) having a refractive index higher than that of the resin.

A material for each of the structures 31 can be selected depending on, for example, a difference in the refractive index from a surrounding material, a wavelength region of incident light to be measured, and the like. For example, in the case of the imaging device 1 that guides infrared light, each of the structures 31 may be configured by amorphous silicon (a-Si), polysilicon, germanium (Ge), or the like.

As described above, the first member 41 is configured using an inorganic material. The first member 41 is formed using an inorganic material such as an oxide, a nitride, or an oxynitride. The first member 41 is configured by, for example, silicon oxide, silicon nitride, silicon nitride oxide, silicon carbide, silicon oxide carbide, or the like. It is to be noted that the first member 41 may be configured by a metal compound such as titanium or hafnium, depending on a difference in the refractive index from the each of the plurality of structures 31, a wavelength region of incident light to be measured, and the like.

As described above, the second member 42 is configured using an organic material. The second member 42 is configured from organic matter such as siloxane, for example. The second member 42 may be configured using a siloxane-based resin, a styrene-based resin, an acrylic-based resin, or the like. The second member 42 may be configured by a material containing fluorine in any of these resins. The second member 42 may be formed using a material in which any of these resins is filled with beads having a refractive index higher than that of the resin.

The light-guiding section 30 causes a phase delay in incoming light due to the difference between the refractive index of each of the structures 31 and the refractive index of the surrounding materials, thus making it possible to exert an influence on a wave front. The light-guiding section 30 provides a phase delay to incident light using each of the structures 31, the first member 41, and the second member 42, for example, thus making it possible to adjust a direction in which light propagates.

A size (size), shape, refractive index, pitch (arrangement interval), and the like of each of the structures 31 are determined to allow light of any wavelength region included in the incident light to travel in a desired direction. In the example illustrated in FIG. 4, the size, shape, refractive index, and pitch of each of the plurality of structures 31 and the refractive indexes and the like of the first member 41 and the second member 42 can be adjusted. As an example, the plurality of structures 31 can be arranged for each pixel P or for each plurality of pixels P, as in the example illustrated in FIG. 5A or 5B.

The light-guiding section 30 is an optical element utilizing material (technology and can be referred to as a light-guiding element being able to guide light. The direction in which the light-guiding section 30 propagates light is adjustable by materials (optical constants) for each of the structures 31, the first member 41, the second member 42, and the like, and the shape, height, pitch (arrangement interval), and the like, of each of the structures 31.

Light from a subject is incident on the photoelectric conversion section 12 of each of the pixels P via the light-guiding section 30. The photoelectric conversion section 12 can receive the light incident via the light-guiding section 30 and perform photoelectric conversion to generate an electrical charge corresponding to a received amount of light. Thus, the imaging device 1 uses a pixel signal to be obtained by means of the photoelectric conversion by the photoelectric conversion section 12 to enable generation of a visible image, an infrared image, or the like, for example. It is possible, in the imaging device 1, to cause the light-guiding section 30 to appropriately guide the light to the photoelectric conversion section 12, thus making it possible to suppress deterioration in sensitivity to incident light.

In this manner, in the present embodiment, the first member 41 and the second member 42 are provided between the plurality of structures 31. This makes it possible to prevent the plurality of structures 31 from collapsing as well as to prevent degradation in the characteristics of the light-guiding section 30. Hereinafter, a description is further given of the imaging device 1 according to the present embodiment in comparison with comparative examples.

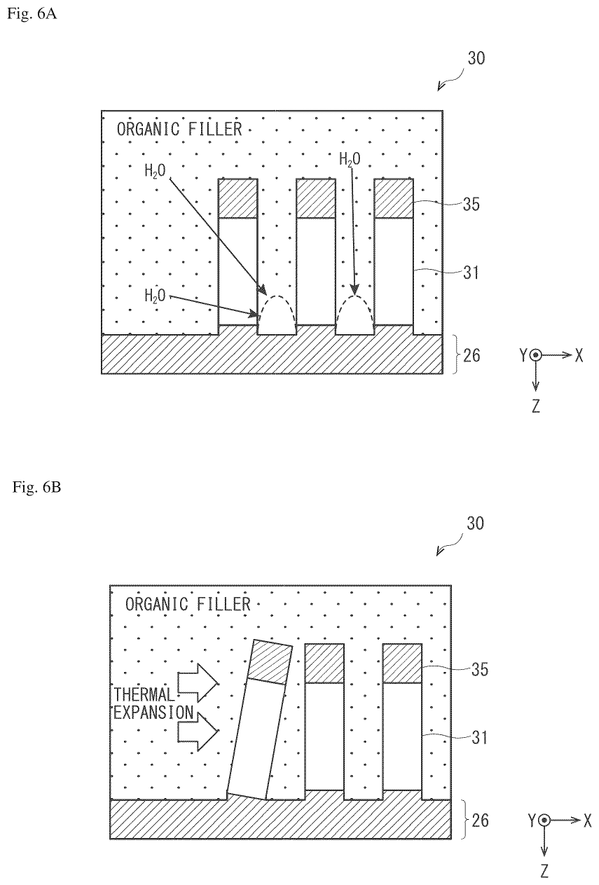

A first comparative example concerns a case where the plurality of structures 31 of the imaging device 1 includes only an organic material as a filling material. In the case of the first comparative example, an organic filler is provided between the plurality of structures 31 as illustrated in FIGS. 6A and 6B. In this case, as illustrated in FIG. 6A, water may accumulate between the plurality of structures 31 due to moisture absorption. In addition, as illustrated in FIG. 6B, the plurality of structures 31 may be inclined due to thermal expansion of the organic material.

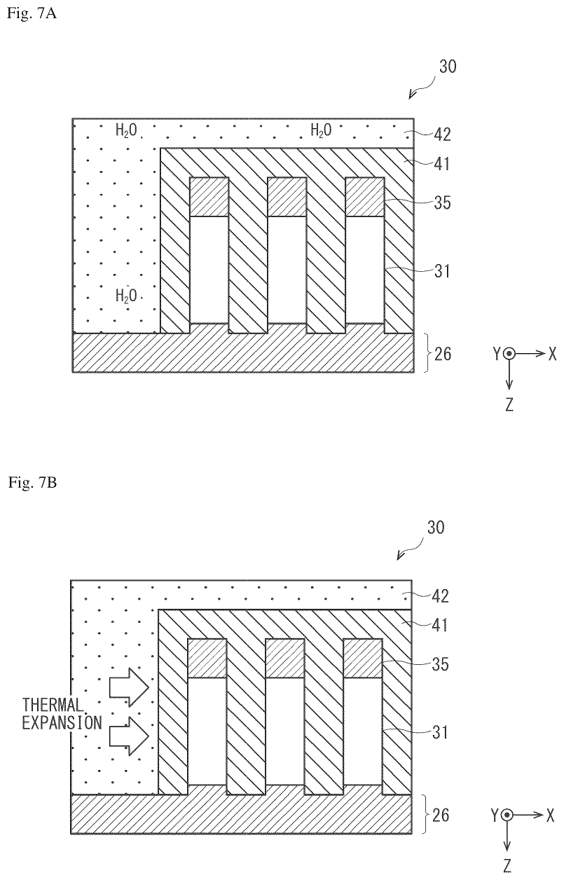

In the present embodiment, as described above, the first member 41 including an inorganic material is provided in contact with the plurality of structures 31, and the second member 42 including an organic material is provided above and around the first member 41. Embedding the first member 41, which is a film including the inorganic material, between the plurality of structures 31, makes it possible to prevent water from entering and accumulating between the plurality of structures 31, as schematically illustrated in FIG. 7A. In addition, providing the first member 41 in contact with the plurality of structures 31 makes it possible to enhance the intensity of the plurality of structures 31 and to prevent the plurality of structures from 31 from collapsing due to thermal expansion, as schematically illustrated in FIG. 7B.

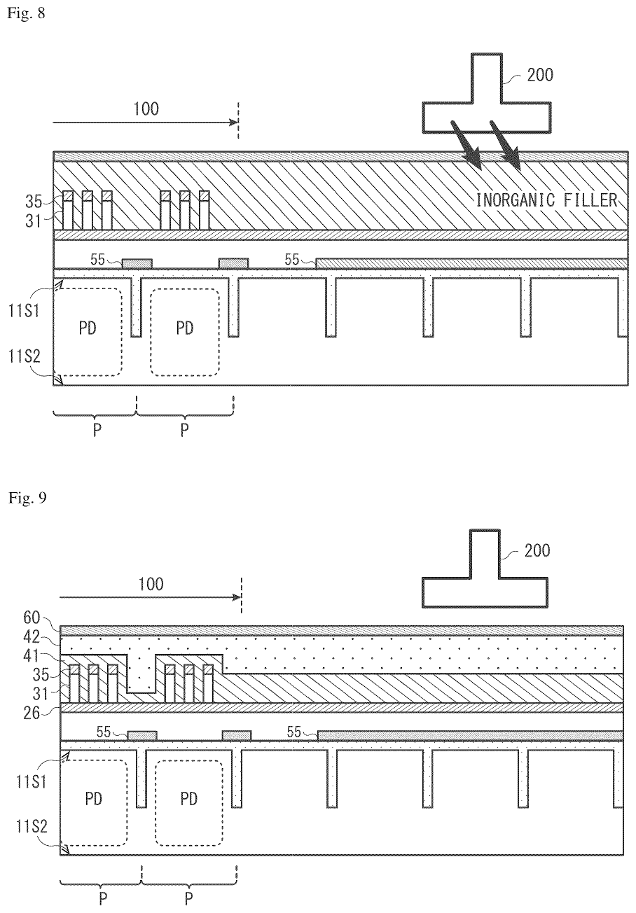

The second comparative example concerns a case where the plurality of structures 31 of the imaging device 1 includes an inorganic material as a filling material. In the case of a second comparative example, as schematically illustrated in FIG. 8, when a collet 200 is used to transfer the imaging device 1 in the form of a semiconductor chip, a great amount of pressure is generated by the inorganic filling material, which may possibly cause the imaging device 1 to be scratched or cracked.

In the present embodiment, as in the example illustrated in FIG. 9, the first member 41 including an inorganic material and the second member 42 including an organic material are provided around the plurality of structures 31, in the pixel section 100 and a region outside the pixel section 100. In a case where the collet 200 is used to transfer the imaging device 1 in the form of a semiconductor chip, the second member 42 including the organic material serves as a buffer layer, thus making it possible to prevent scratching or cracking on the imaging device 1.

FIG. 10 is an explanatory diagram of a configuration example of the light-guiding section of the imaging device according to the embodiment. FIG. 10 illustrates a configuration example of the light-guiding section 30 when guiding light at a wavelength of 940 nm. The plurality of structures 31 is configured by amorphous silicon (a-Si). The thickness (height) of the plurality of structures is denoted by h1 and is 720 nm to 880 nm. In addition, the antireflection film 35 is configured by a SiN film. The thickness (film thickness) h2 of the antireflection film 35 is 90 nm to 110 nm.

The first member 41 is configured by an SiO film. The thickness of a portion h3 of the first member 41, above the antireflection film 35, is 135 nm to 165 nm. The second member 42 is configured by a fluorine-containing siloxane resin. The thickness of a portion H4 of the second member 42, above the first member 41 is 80 nm to 100 nm. In addition, the protective film 60 is configured by a SiO film. The thickness h5 of the protective film 60 is 145 nm to 180 nm.

As described above, in the present embodiment, the first member 41 including an inorganic material and the second member 42 including an organic material are arranged in combination within the light-guiding section 30. This makes it possible to reduce reflection in the plurality of structures 31. In the case of the example illustrated in FIG. 10, for example, a reflectance to incident light of a wavelength of 940 nm is about 16%.

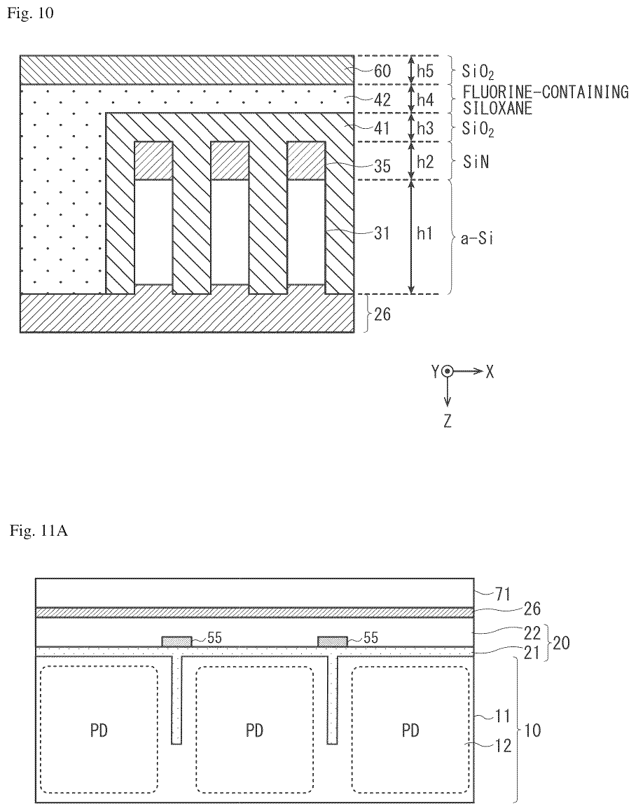

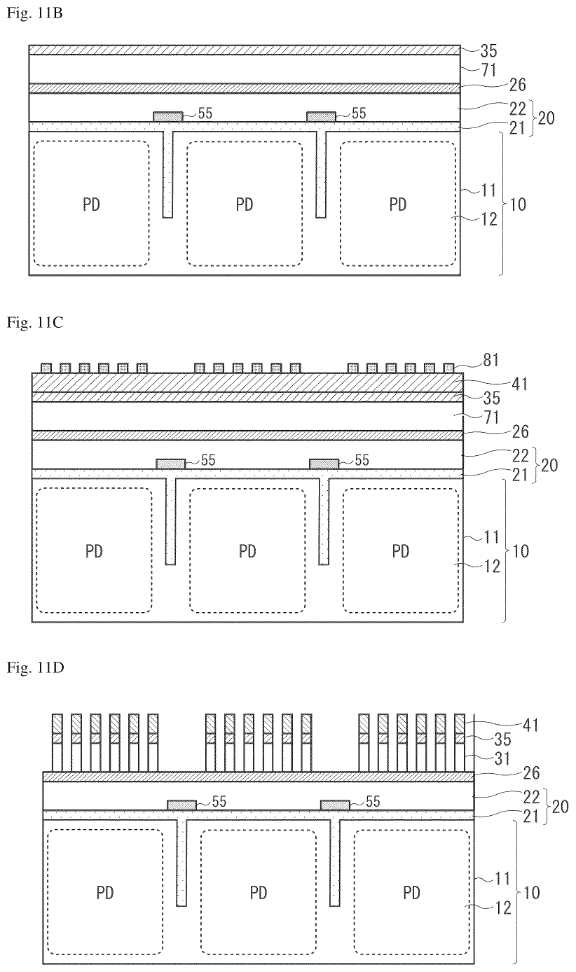

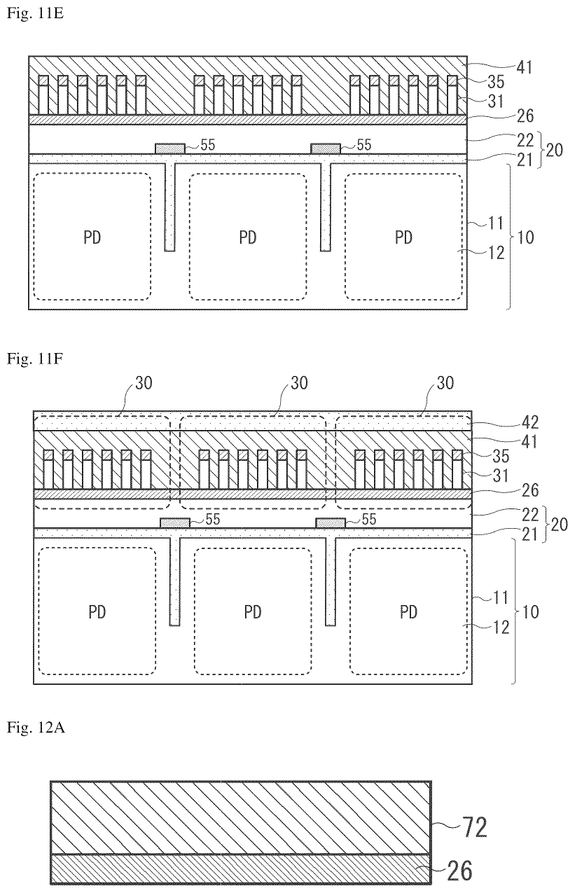

FIGS. 11A to 11F are each a diagram illustrating an example of a method of manufacturing the imaging device according to an embodiment. First, as illustrated in FIG. 11A, the antireflection film 26, or the like, is formed on the semiconductor substrate 11 in which an element such as the photoelectric conversion section 12 is formed. Thereafter, an a-Si film 71 (amorphous silicon film) is formed on the antireflection film 26. Then, as illustrated in FIG. 11B, a SiN film is formed as the antireflection film 35 on the a-Si film 71.

Next, as illustrated in FIG. 11C, an SiO film is formed as the first member 41, and thereafter a resist film 81 is formed by lithography and etching. Then, as illustrated in FIG. 11D, dry etching or wet etching is performed on the first member 41, the antireflection film 35, and the a-Si film 71. This removes an excess portion of the a-Si film 71, thus allowing the plurality of structures 31 to be formed.

Next, as illustrated in FIG. 11E, the SiO film is formed by Atomic Layer Deposition ALD to form the first member 41. Then, as illustrated in FIG. 11F, a resin material is applied to form the second member 42. Then, the protective film 60 is formed on the second member 42. Through the above-described manufacturing method, it is possible to manufacture the imaging device 1 illustrated in FIG. 4 or other diagrams.

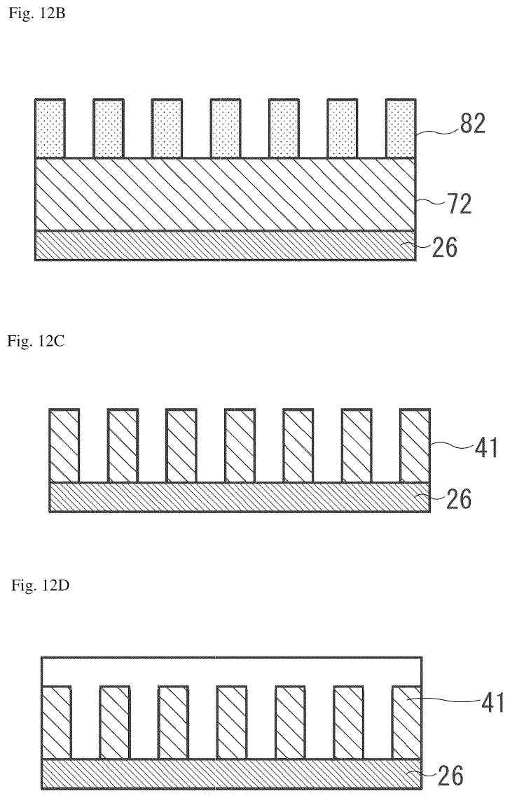

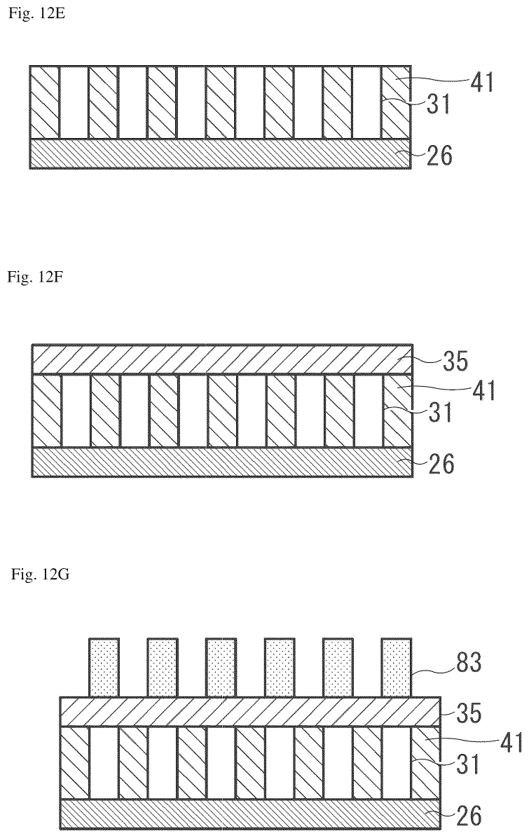

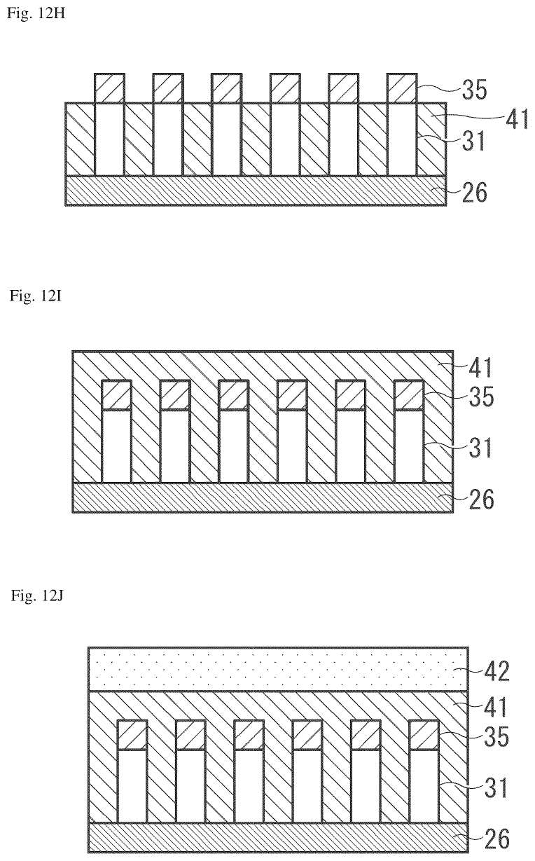

FIGS. 12A to 12J are each a diagram illustrating another example of the method of manufacturing the imaging device according to the embodiment. FIGS. 12A to 12J each illustrate a method of manufacturing the light-guiding section 30. First, as illustrated in FIG. 12A, a transparent inorganic filling member 72 is formed as a material for the first member 41 on the antireflection film 26.

Next, as illustrated in FIG. 12B, a resist film 82 is formed by lithography and etching. Then, as illustrated in FIG. 12C, the inorganic filling member 72 is selectively removed by etching to form the first member 41.

Next, as illustrated in FIG. 12D, a pillar material is formed as a film, and thereafter, as illustrated in FIG. 12E, chemical-mechanical polishing (CMP) or etching is performed to thereby form the plurality of structures 31. In addition, as illustrated in FIG. 12F, the antireflection film 35 is formed. Then, as illustrated in FIG. 12G, a resist film 83 is formed on the antireflection film 35 by lithography and etching.

Next, as illustrated in FIG. 12H, the antireflection film 35 is selectively removed by etching. In addition, as illustrated in FIG. 12I, the first member 41 is formed. Then, as illustrated in FIG. 12J, the second member 42 is formed. Through the above-described manufacturing method as well, it is possible to manufacture the imaging device 1 illustrated in FIG. 4 or other diagrams. It is to be noted that the above-described manufacturing method is merely exemplary, and another manufacturing method may also be employed.

### Workings and Effects

The photodetector according to the present embodiment includes a light-guiding section (lightguide 30) including a plurality of structures (structures 31) each having a size equal to or less than a wavelength of incident light, a first material (first member 41), a second material (second member 42), wherein a combination of the first material and the second material is provided above and/or between the plurality of structures and wherein the first material and the second material each has a refractive index different from a refractive index of the plurality of structures and a photoelectric conversion section (photoelectric converter 12) that photoelectrically converts light incident via the light-guiding section.

In the photodetector (imaging device 1) according to the present embodiment, the first member 41 and the second member 42 are provided between the plurality of structures 31. It is therefore possible to prevent the plurality of structures from collapsing as well as to prevent degradation in the characteristics of the light-guiding section 30. It is possible to prevent deterioration in quality with the photodetector according to the present embodiment.

Next, descriptions are given of modification examples of the present disclosure. Hereinafter, components similar to those of the foregoing embodiment are denoted by the same reference numerals, and descriptions thereof are omitted as appropriate.

### 2. Modification Examples

### 2-1. Modification Example 1

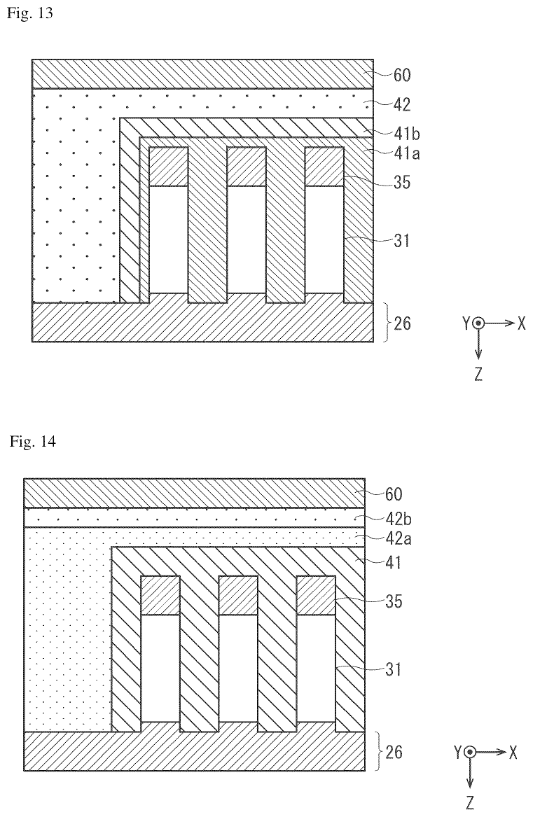

FIG. 13 is a diagram illustrating a configuration example of a light-guiding section of an imaging device according to Modification Example 1 of the present disclosure. The light-guiding section 30 may be configured using a plurality of first members 41 and a plurality of second members 42. For example, as in the example illustrated in FIG. 13, the light-guiding section 30 may include a first member 41a and a first member 41b. The first member 41a and the first member 41b are each configured using, for example, an inorganic material. The first member 41a and the first member 41b may be configured using different inorganic materials.

In the example illustrated in FIG. 13, the first member 41a is provided in contact with the plurality of structures 31. The first member 41b is provided on the first member 41a and is formed to cover the first member 41a. The second member 42 is stacked on the first member 41b and is in contact with the first member 41b. Also, in the case of the present modification example, it is possible to achieve effects like those of the foregoing embodiment.

### 2-2. Modification Example 2

FIG. 14 is a diagram illustrating a configuration example of a light-guiding section of an imaging device according to Modification Example 2. As in the example illustrated in FIG. 14, the light-guiding section 30 may include a second member 42a and a second member 42b. The second member 42a and the second member 42b are each configured using, for example, an organic material. The second member 42a and the second member 42b may be configured using different organic materials.

In the example illustrated in FIG. 14, the second member 42a is provided in contact with the first member 41. The second member 42b is provided on the second member 42a and is formed to cover the second member 42a. Also, in the case of the present modification example, it is possible to achieve effects like those of the foregoing embodiment.

### 2-3. Modification Example 3

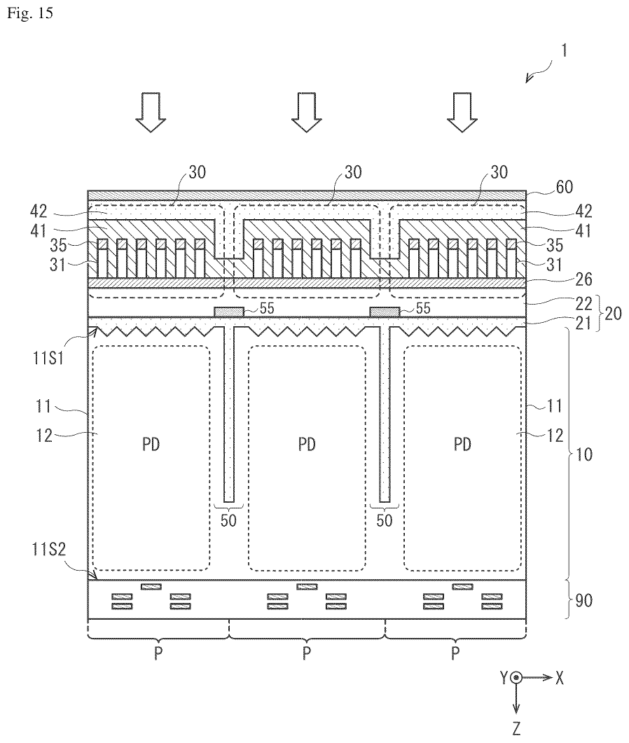

FIG. 15 is a diagram illustrating a configuration example of an imaging device according to Modification Example 3. As schematically illustrated in FIG. 15, the photoelectric conversion section 12 of the imaging device 1 may have an irregular shape, (e.g., a quadrangular pyramid shape) on the first surface 11S1 of the semiconductor substrate 11. That is, the imaging device 1 includes the photoelectric conversion section 12 having a groove structure of an inverted quadrangular pyramid shape on the light-receiving surface and has a moth-eye structure.

The imaging device 1 according to the present modification example has a structure in which fine irregularities are formed in a region above the photoelectric conversion section 12 of each of the pixels P. The photoelectric conversion section 12 includes a plurality of concave parts and convex parts and can be said to have an irregular structure. In this case, it is possible to efficiently guide light to the photoelectric conversion section 12, thus making it possible to improve sensitivity to incident light.

### 2-4. Modification Example 4

The description has been given, in the foregoing embodiment and modification examples, of the configuration example of the light-guiding section 30 including the plurality of structures 31. The shape of the plurality of structures 31 of the light-guiding section 30 is not limited to the foregoing example. The shape of the plurality of structures 31 is appropriately modifiable, and may be, for example, a quadrangular shape in a plan view. In addition, the shape of the plurality of structures 31 may be a polygon, an ellipse, a cross, or another shape.

### 2-5. Modification Example 5

The imaging device 1 may include a lens section and a color filter. The lens section is provided above the light-guiding section 30, for example, to guide light incident from above to a side of the light-guiding section 30. The color filter is configured to selectively transmit light of a particular wavelength region of incoming light. The color filter is provided, for example, between the light-guiding section 30 and the photoelectric conversion section 12. The color filter is, for example, a color filter of a primary color system red, blue, and green (RGB). In addition, a color filter of a complementary color system such as cyan (Cy), magenta (Mg), or yellow (Ye) may be arranged.

### 2-6. Modification Example 6

The light-guiding section 30, which is an optical element, may be configured as a light-dispersing section (light disperser) that is able to disperse light, through design of the plurality of structures. In this case, the light-guiding section 30 can also be referred to as a splitter (e.g., a color splitter). In addition, for example, the light-guiding section 30 may be configured as a lens or a plurality of lenses that condenses light. In addition, the light-guiding section 30 may be configured as a filter that selectively transmits light of a particular wavelength region of incoming light. The photodetector and the optical element (light-guiding section 30) according to the present disclosure are applicable to various apparatuses.

### 3. Application Example

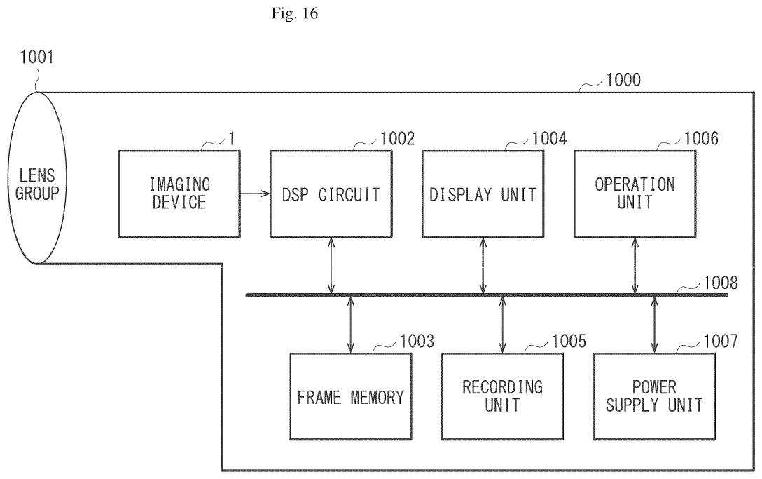

The above-described imaging device 1 or the like, is applicable, for example, in any type of electronic apparatus having an imaging function including a camera system such as a digital still camera or a video camera, a mobile phone, and the like. FIG. 16 illustrates a schematic configuration of an electronic apparatus 1000.

The electronic apparatus 1000 includes, for example, a lens group 1001, the imaging device 1, a Digital Signal Processor (DSP) circuit 1002, a frame memory 1003, a display unit 1004, a recording unit 1005, an operation unit 1006, and a power supply unit 1007. They are coupled to each other via bus line 1008.

The lens group 1001 takes in incident light (image light) from a subject and forms an image on an imaging surface of the imaging device 1. The imaging device 1 converts the amount of incident light formed as an image on the imaging surface by the lens group 1001 into electrical signals on a pixel-by-pixel basis and supplies the DSP circuit 1002 with the electrical signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic Electro Luminescence (EL) panel, and records image data of a moving image or a still image captured by the imaging device 1 on a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot, or the like.

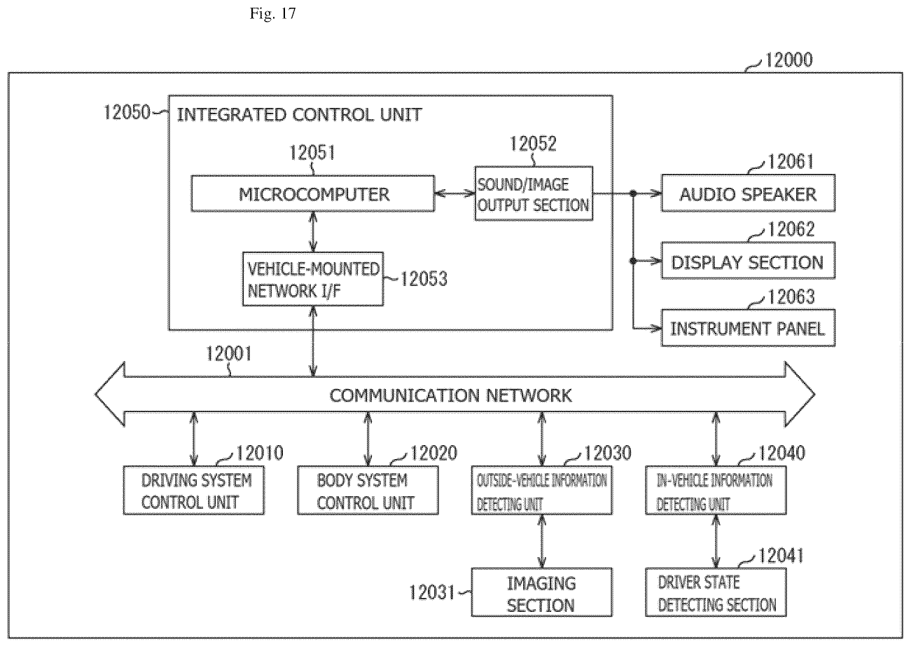

FIG. 17 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches, can be input to the body system control unit 12020. The body system control unit 12020 receives these input radio waves or signals, and controls a door lock device, the power window device, the lamps, or the like, of the vehicle.

The outside-vehicle information detecting unit 12030 detects information about the outside of the vehicle including the vehicle control system 12000. For example, the outside-vehicle information detecting unit 12030 is connected to an imaging section 12031. The outside-vehicle information detecting unit 12030 instructs the imaging section 12031 to provide an of the outside of the vehicle and then receives the image from the imaging section 12031. Based on the received image, the outside-vehicle information detecting unit 12030 processes the received image to detect objects such as a human, a vehicle, an obstacle, a sign, a character on a road surface, or the like, or processes the received image to detect distances from the objects.

The imaging section 12031 is an optical sensor that receives light and outputs an electrical signal corresponding to a received amount of light. The imaging section 12031 can output the electric signal as an image or can output the electrical signal as information about a measured distance. In addition, the light received by the imaging section 12031 may be visible light or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. Based on detection information input from the driver state detecting section 12041, the in-vehicle information detecting unit 12040 may calculate a degree of fatigue of the driver or a degree of concentration of the driver or may determine whether the driver is dozing off.

The microcomputer 12051 can calculate a control target value for the driving force generating device, the steering mechanism, or the braking device based on the information about the inside or outside of the vehicle obtained by the outside-vehicle information detecting unit 12030 or the in-vehicle information detecting unit 12040 and can output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, (e.g., operating the vehicle without input from the driver, or the like), by controlling the driving force generating device, the steering mechanism, the braking device, or the like, based on the information about the outside or inside of the vehicle obtained by the outside-vehicle information detecting unit 12030 or the in-vehicle information detecting unit 12040.

In addition, the microcomputer 12051 can output a control command to the body system control unit 12020 based on the information about the outside of the vehicle obtained by the outside-vehicle information detecting unit 12030. For example, the microcomputer 12051 can perform cooperative control intended to prevent a glare by controlling the headlamp to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

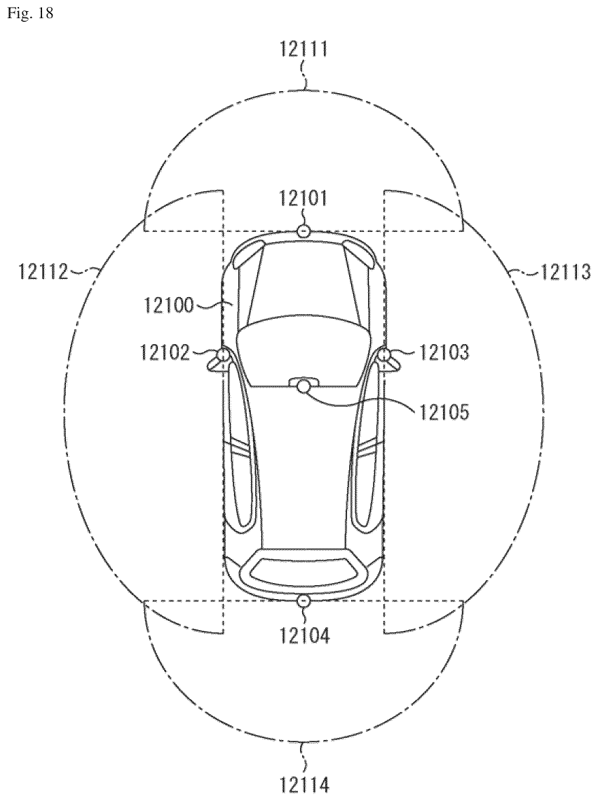

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle, obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door, obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) based on the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance and perform automatic brake control (including following stop control), automatic acceleration control (including following start control), or the like. It is thus possible to perform cooperative control intended for automated driving that allows the vehicle to operate in an automated manner without depending on input from the driver, or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects based on the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the micro-computer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062 and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether there is a pedestrian in images of the imaging sections 12101 to 12104. Such recognition of a pedestrian is, for example, performed by a procedure of extracting characteristic points in the images of the imaging sections 12101 to 12104 as infrared cameras and a procedure of determining whether it is the pedestrian by performing pattern matching processing on a series of characteristic points representing the contour of the object. When the microcomputer 12051 determines that there is a pedestrian in the images of the imaging sections 12101 to 12104, and thus recognizes the pedestrian, the sound/image output section 12052 controls the display section 12062 so that a square contour line for emphasis is displayed to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables one to obtain images having high definition, thus making it possible to perform highly accurate control utilizing the image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

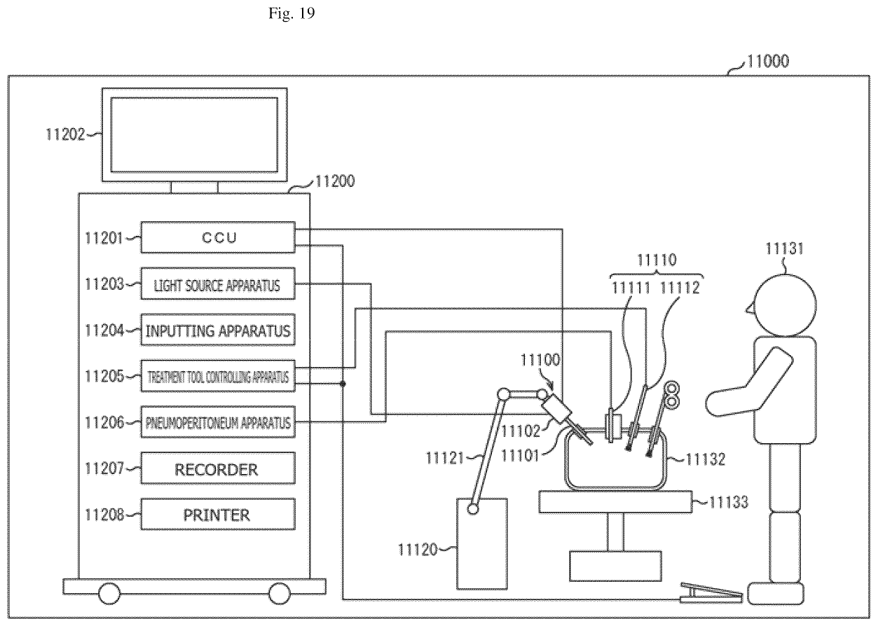

FIG. 19 is a view depicting an example of a schematic configuration of an endoscopic surgery system to which the technology according to an embodiment of the present disclosure (present technology) can be applied.

In FIG. 19, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 includes as a rigid endoscope having the lens barrel 11101 of the hard type. However, the endoscope 11100 may otherwise be included as a flexible endoscope having the lens barrel 11101 of the flexible type.

The lens barrel 11101 has at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pick-up element are provided in the inside of the camera head 11102 such that reflected light (observation light) from the observation target is condensed on the image pick-up element by the optical system. The observation light is photo-electrically converted by the image pick-up element to generate an electric signal corresponding to the observation light, namely, an image signal corresponding to an observation image. The image signal is transmitted as raw data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (e.g., demosaic processing).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user may input an instruction, or the like, to change an image pick-up condition (type of irradiation light, magnification, focal distance or the like) by the endoscope 11100.

A treatment tool controlling apparatus 11205 controls driving of the energy device 11112 for cautery or incision of a tissue, sealing of a blood vessel, or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustments to the white balance of a picked-up image can be performed by the light source apparatus 11203. Further, in this case, if laser beams from the respective RGB laser light sources are irradiated time-divisionally on an observation target and driving of the image pick-up elements of the camera head 11102 are controlled in a synchronous manner with the irradiation timings. Then images individually corresponding to the R, G and B colors can be also picked up time-divisionally. According to this method, a color image can be obtained even if color filters are not provided for the image pick-up element.

Further, the light source apparatus 11203 may be controlled such that the intensity of light to be output is changed for each predetermined time. By controlling the driving of the image pick-up element of the camera head 11102 in synchronism with the timing of the change of the intensity of light to acquire images time-divisionally and synthesizing the images, an image of a high dynamic range, free from underexposed blocked up shadows and overexposed highlights, can be created.

Further, the light source apparatus 11203 may be configured to supply light of a pre-determined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observations, it is possible to perform observations of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

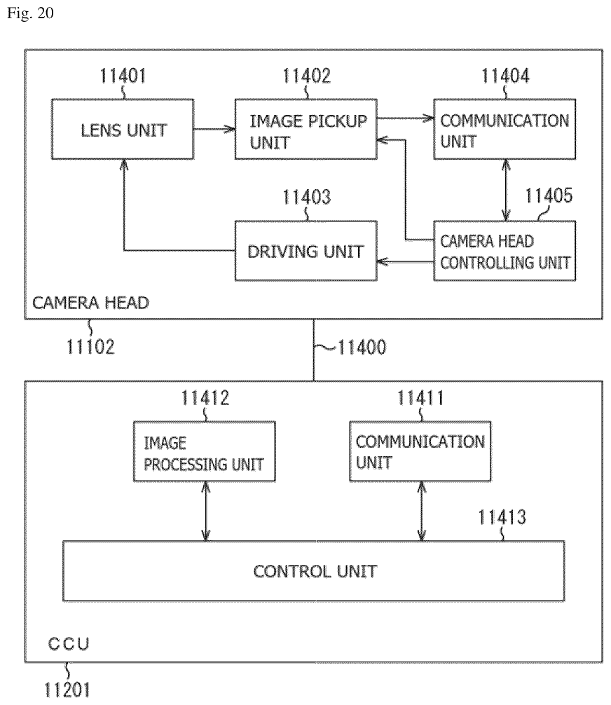

FIG. 20 is a block diagram depicting an example of a functional configuration of the camera head 11102 and the CCU 11201 depicted in FIG. 19.

The camera head 11102 includes a lens unit 11401, an image pick-up unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pick-up elements which is included by the image pick-up unit 11402 may be one (single-plate type) or a plural number (multi-plate type). Where the image pick-up unit 11402 is configured as that of the multi-plate type, for example, image signals corresponding to respective R, G and B are generated by the image pick-up elements, and the image signals may be synthesized to obtain a color image. The image pick-up unit 11402 may also be configured so as to have a pair of image pick-up elements for acquiring respective image signals for the right eye and the left eye ready for three-dimensional (3D) display. If 3D display is performed, then the depth of a living body tissue in a surgical region can be comprehended more accurately by the surgeon 11131. It is to be noted that, where the image pick-up unit 11402 is configured as a stereoscopic type, a plurality of systems of lens units 11401 are provided corresponding to the individual image pick-up elements.

Further, the image pick-up unit 11402 may not necessarily be provided on the camera head 11102. For example, the image pick-up unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked-up image by the image pick-up unit 11402 can be suitably adjusted.

The communication unit 11404 includes a communication apparatus for transmitting and receiving various kinds of information to and from the CCU 11201. The communication unit 11404 transmits an image signal acquired from the image pick-up unit 11402 as raw data to the CCU 11201 through the transmission cable 11400.

In addition, the communication unit 11404 receives a control signal for driving the camera head 11102 from the CCU 11201 and supplies the control signal to the camera head controlling unit 11405. The control signal includes information relating to image pick-up conditions such as, for example, information that a frame rate of a picked-up image is designated, information that an exposure value upon image pick-up is designated and/or information that a magnification and a focal point of a picked-up image are designated.

It is to be noted that the image pick-up conditions such as the frame rate, exposure value, magnification or focal point may be designated by the user or may be set automatically by the control unit 11413 of the CCU 11201 based on an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 based on a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for driving of the camera head 11102 to the camera head 11102. The image signal and the control signal can be transmitted by electrical communication, optical communication, or the like.

The image processing unit 11412 performs various image processes for an image signal in the form of raw data transmitted thereto from the camera head 11102.

The control unit 11413 performs various kinds of control processes relating to image pick-up of a surgical region, or the like, by the endoscope 11100 and display of the picked-up image, or the like. For example, the control unit 11413 creates a control signal for driving of the camera head 11102.

Further, the control unit 11413 controls, based on an image signal for which image processes have been performed by the image processing unit 11412, the display apparatus 11202 to display a picked-up image in which the surgical region or the like is imaged. Thereupon, the control unit 11413 may recognize various objects in the picked-up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked-up image. The control unit 11413 may cause, when controlling the display apparatus 11202 to display a picked-up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both electrical and optical communications.

Here, while, in the example depicted, communication is performed by wired communication using the transmission cable 11400, the communication between the camera head 11102 and the CCU 11201, however, may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pick-up unit 11402 provided in the camera head 11102 of the endoscope 11100 of the configurations described above. Applying the technology according to an embodiment of the present disclosure to the image pick-up unit 11402 enables the image pick-up unit 11402 to have high sensitivity, thus making it possible to provide the endoscope 11100 having high definition.

Although the description has been given hereinabove of the present disclosure with reference to the embodiment, the modification examples, the application example, and the practical application examples, the present technology is not limited to the foregoing embodiment and the like and may be modified in a wide variety of ways. For example, although the foregoing modification examples have been described as modification examples of the foregoing embodiment, the configurations of the respective modification examples may be combined as appropriate.

In the foregoing embodiment and the like, the imaging device is exemplified and described; however, it is sufficient for the photodetector of the present disclosure, for example, to receive incident light and convert the light into electrical charge. The output signal may be a signal of image information or a signal of ranging information. The photodetector (imaging device) is applicable to an image sensor, a distance measurement sensor, or the like.

The photodetector according to the present disclosure is applicable also as a distance measurement sensor enabling distance measurement of a time-of-flight (TOF) method. The photodetector (imaging device) is applicable also as a sensor enabling detection of an event, e.g., an event-driven sensor (referred to as Event Vision Sensor (EVS), Event Driven Sensor (EDS), Dynamic Vision Sensor (DVS), etc.).

A photodetector according to an embodiment of the present disclosure includes a lightguide including a plurality of structures each having a size equal to or less than a wavelength of incident light, a first material, a second medium, wherein a combination of the first material and the second material is provided above and/or between the plurality of structures and wherein the first material and the second material each has a refractive index different from a refractive index of the plurality of structures and a photoelectric conversion section that photoelectrically converts light incident via the light-guide. It is therefore possible to prevent the plurality of structures from collapsing as well as to prevent degradation in the characteristics of the light-guide. It is possible to prevent deterioration in quality with the photodetector according to the embodiment of the present disclosure.

An optical element according to an embodiment of the present disclosure includes a plurality of structures each having a size equal to or less than a wavelength of incident light, and a first material and a second material, wherein a combination of the first material and the second material is provided above and/or between the plurality of structures. Each of the first material and the second material has a refractive index different from a refractive index of the plurality of structures. It is therefore possible to prevent the plurality of structures from collapsing and to prevent degradation in the characteristics of the optical element. It is possible to prevent deterioration in quality of the optical element according to the embodiment of the present disclosure.

It is to be noted that the effects described herein are merely exemplary and are not limited to the description and may further include other effects. In addition, the present disclosure may also have the following configurations.
(1)
A photodetector including:
a light-guiding section including a plurality of structures each having a size equal to or less than a wavelength of incident light, and a first medium and a second medium provided to fill between the plurality of structures adjacent to each other, the first medium and the second medium each having a refractive index different from a refractive index of the structure; and
a photoelectric conversion section that photoelectrically converts light incident via the light-guiding section.
(2)
The photodetector according to (1), in which
the first medium is provided in contact with the structure and includes an inorganic material, and
the second medium is provided to cover the first medium and includes an organic material.
(3)
The photodetector according to (1) or (2), in which
the first medium is provided to cover the plurality of structures, and
the second medium is provided to cover the first medium.
(4)
The photodetector according to any one of (1) to (3), in which the refractive index of the structure is higher than the refractive index of the first medium.
(5)
The photodetector according to any one of (1) to (4), in which a difference between the refractive index of the structure and the refractive index of the first medium is 0.3 or more.
(6)
The photodetector according to any one of (1) to (5), in which the refractive index of the first medium is higher than the refractive index of the second medium.
(7)
The photodetector according to any one of (1) to (6), in which the light-guiding section includes the plurality of structures having different sizes, shapes, or arrangement pitches.
(8)
The photodetector according to any one of (1) to (7), in which the light-guiding section includes the plurality of structures each having a columnar shape.
(9)
The photodetector according to any one of (1) to (8), in which the structure has a size equal to or less than a wavelength of visible light or a size equal to or less than a wavelength of infrared light.
(10)
An optical element including:
a plurality of structures each having a size equal to or less than a wavelength of incident light; and
a first medium and a second medium provided to fill between the plurality of structures adjacent to each other, the first medium and the second medium each having a refractive index different from a refractive index of the structure.
(11)
The optical element according to (10), in which
the first medium is provided in contact with the structure and includes an inorganic material, and
the second medium is provided to cover the first medium and includes an organic material.
(12)
The optical element according to (10) or (11), in which
the first medium is provided to cover the plurality of structures, and
the second medium is provided to cover the first medium.
(13)
The optical element according to any one of (10) to (12), in which the refractive index of the structure is higher than the refractive index of the first medium.
(14)
The optical element according to any one of (10) to (13), in which a difference between the refractive index of the structure and the refractive index of the first medium is 0.3 or more.
(15)
The optical element according to any one of (10) to (14), in which the refractive index of the first medium is higher than the refractive index of the second medium.
(16)
The optical element according to any one of (10) to (15), in which the plurality of structures includes a plurality of structures having different sizes, shapes, or arrangement pitches.
(17)
The optical element according to any one of (10) to (16), in which the plurality of structures includes a structure having a columnar shape.
(18)
The optical element according to any one of (10) to (17), in which the structure has a size equal to or less than a wavelength of visible light or a size equal to or less than a wavelength of infrared light.
(19)
An electronic apparatus including:
an optical system; and
a photodetector that receives light transmitted through the optical system, the photodetector including:
a light-guiding section including a plurality of structures each having a size equal to or less than a wavelength of incident light, and a first medium and a second medium provided to fill between the plurality of structures adjacent to each other, the first medium and the second medium each having a refractive index different from a refractive index of the structure, and
a photoelectric conversion section that photoelectrically converts light incident via the light-guiding section.
(20)
A photodetector, comprising:
a light guide including a plurality of structures each having a size equal to or less than a wavelength of incident light;
a first material;
a second material;
wherein a combination of the first material and the second material is provided above and/or between the plurality of structures and
wherein the first material and the second material each has a refractive index different from a refractive index of the plurality of structures; and
a photoelectric converter that photoelectrically converts light incident via the light guide.
(21)
The photodetector according to (20), wherein
the first material contacts the plurality of structures and includes an inorganic material, and
the second material covers the first material and includes an organic material.
(22)
The photodetector according to (20) or (21), wherein
the first material covers the plurality of structures, and
the second material covers the first material.
(23)
The photodetector according to (20) to (22), wherein the refractive index of the plurality of structures is higher than the refractive index of the first material.
(24)
The photodetector according to (20) to (23), wherein a difference between the refractive index of the plurality of structures and the refractive index of the first material is 0.3 or more.
(25)
The photodetector according to (20) to (24), wherein the refractive index of the first material is higher than the refractive index of the second material.
(26)
The photodetector according to (20) to (25), wherein the plurality of structures includes structures having different sizes, different shapes, or different pitch arrangements.
(27)
The photodetector according to (20) to (26), wherein each structure of the plurality of structures has a columnar shape.
(28)
The photodetector according to (20) to (27), wherein each structure of the plurality of structures has a size equal to or less than a wavelength of visible light or a size equal to or less than a wavelength of infrared light.
(29)
An optical element, comprising:
a plurality of structures each having a size equal to or less than a wavelength of incident light;
a first material; and
a second material;
wherein a combination of the first material and the second material is provided above and/or between the plurality of structures and
wherein the first material and the second material each has a refractive index different from a refractive index of the plurality of structures.
(30)
The optical element according to (29), wherein the first material contacts the plurality of structures and includes an inorganic material, and
the second material covers the first material and includes an organic material.
(31)
The optical element according to (29) or (30), wherein
the first material covers the plurality of structures, and
the second material covers the first medium.
(32)
The optical element according to (29) to (31), wherein the refractive index of the plurality of structures is higher than the refractive index of the first material.
(33)
The optical element according to (29) to (32), wherein a difference between the refractive index of the plurality of structures and the refractive index of the first material is 0.3 or more.
(34)
The optical element according to (29) to (33), wherein the refractive index of the first material is higher than the refractive index of the second material.
(35)
The optical element according to (29) to (34), wherein the plurality of structures includes structures having different sizes, different shapes, or different pitch arrangements.
(36)
The optical element according to (29) to (35), wherein each structure of the plurality of structures has a columnar shape.
(37)
The optical element according to (29) to (36), wherein each structure of the plurality of structures has a size equal to or less than a wavelength of visible light or a size equal to or less than a wavelength of infrared light.
(38)
An electronic apparatus, comprising:
an optical system; and
a photodetector that receives light transmitted through the optical system,
the photodetector including:
a light guide including a plurality of structures each having a size equal to or less than a wavelength of incident light;
a first material;
a second material;
wherein a combination of the first material and the second material is provided above and/or between the plurality of structures and
the first material and the second material each has a refractive index different from a refractive index of the plurality of structures; and
a photoelectric converter that photoelectrically converts light incident via the light guide.
(39)
The electronic apparatus according to (38), wherein
the first contacts the plurality of structures and includes an inorganic material, and
the second material covers the first material and includes an organic material.

It should be understood by those skilled in the art that various modifications, combinations, sub-combinations and alterations may occur depending on design requirements and other factors insofar as they are within the scope of the appended claims or the equivalents thereof.

### REFERENCE NUMERALS LIST

1 imaging device
10 light-receiving section
12 photoelectric conversion section
20 insulating layer
21, 22 insulating film
26, 35 antireflection film
30 light-guiding section
31 structure
41 first member
42 second member.

What is claimed is:

1. A photodetector, comprising:
a light guide including a plurality of structures each having a size equal to or less than a wavelength of incident light;
a first material;
a second material;
wherein a combination of the first material and the second material is provided above and/or between the plurality of structures and
wherein the first material and the second material each has a refractive index different from a refractive index of the plurality of structures; and
a photoelectric converter that photoelectrically converts light incident via the light guide.

2. The photodetector according to claim 1, wherein
the first material contacts the plurality of structures and includes an inorganic material, and
the second material covers the first material and includes an organic material.

3. The photodetector according to claim 2, wherein
the first material covers the plurality of structures, and
the second material covers the first material.

4. The photodetector according to claim 2, wherein the refractive index of the plurality of structures is higher than the refractive index of the first material.

5. The photodetector according to claim 4, wherein a difference between the refractive index of the plurality of structures and the refractive index of the first material is 0.3 or more.

6. The photodetector according to claim 2, wherein the refractive index of the first material is higher than the refractive index of the second material.

7. The photodetector according to claim 1, wherein the plurality of structures includes structures having different sizes, different shapes, or different pitch arrangements.

8. The photodetector according to claim 1, wherein each structure of the plurality of structures has a columnar shape.

9. The photodetector according to claim 1, wherein each structure of the plurality of structures has a size equal to or less than a wavelength of visible light or a size equal to or less than a wavelength of infrared light.

10. An optical element, comprising:
a plurality of structures each having a size equal to or less than a wavelength of incident light;
a first material; and
a second material;
wherein a combination of the first material and the second material is provided above and/or between the plurality of structures and
wherein the first material and the second material each has a refractive index different from a refractive index of the plurality of structures.

11. The optical element according to claim 10, wherein
the first material contacts the plurality of structures and includes an inorganic material, and
the second material covers the first material and includes an organic material.

12. The optical element according to claim 11, wherein
the first material covers the plurality of structures, and
the second material covers the first medium.

13. The optical element according to claim 11, wherein the refractive index of the plurality of structures is higher than the refractive index of the first material.

14. The optical element according to claim 13, wherein a difference between the refractive index of the plurality of structures and the refractive index of the first material is 0.3 or more.

15. The optical element according to claim 11, wherein the refractive index of the first material is higher than the refractive index of the second material.

16. The optical element according to claim 10, wherein the plurality of structures includes structures having different sizes, different shapes, or different pitch arrangements.

17. The optical element according to claim 10, wherein each structure of the plurality of structures has a columnar shape.

18. The optical element according to claim 10, wherein each structure of the plurality of structures has a size equal to or less than a wavelength of visible light or a size equal to or less than a wavelength of infrared light.

19. An electronic apparatus, comprising:
an optical system; and
a photodetector that receives light transmitted through the optical system,
the photodetector including:
a light guide including a plurality of structures each having a size equal to or less than a wavelength of incident light;
a first material;
a second material;
wherein a combination of the first material and the second material is provided above and/or between the plurality of structures and
the first material and the second material each has a refractive index different from a refractive index of the plurality of structures; and
a photoelectric converter that photoelectrically converts light incident via the light guide.

20. The electronic apparatus according to claim 19, wherein
the first material contacts the plurality of structures and includes an inorganic material, and
the second material covers the first material and includes an organic material.
